(19) United States
(12) Patent Application Publication
(10) Pub. No.: US 2025/0171890 A1
(43) Pub. Date: May 29, 2025

(54) EMBEDDING METHOD AND SUBSTRATE PROCESSING APPARATUS

(71) Applicant: Tokyo Electron Limited, Tokyo (JP)

(72) Inventors: Isao GUNJI, Yamanashi (JP); Daisuke OBA, Yamanashi (JP); Hiroyuki IKUTA, Yamanashi (JP); Yoshinori MORISADA, Yamanashi (JP)

(21) Appl. No.: 18/842,553

(22) PCT Filed: Feb. 24, 2023
(86) PCT No.: PCT/JP2023/006750

§ 371 Date: Aug. 29, 2024

(30) Foreign Application Priority Data
Mar. 10, 2022 (JP) 2022-037479

(51) Int. Cl. C23C 16/04; C23C 16/30; C23C 16/56; H01L 21/02

(52) U.S. Cl. CPC C23C 16/045; C23C 16/30; C23C 16/56; H01L 21/02274; H01L 21/0234

(57) ABSTRACT

An embedding method of embedding a film in a recess of a substrate is provided. The embedding method includes: (a) preparing a substrate having a recess on a mounting table arranged in a chamber of a substrate processing apparatus; (b) forming a flowable film in the recess; and (c) performing a first modification on the flowable film with a plasma generated by supplying RF power to the mounting table.

### TECHNICAL FIELD

The present disclosure relates to an embedding method and a substrate processing apparatus.

### BACKGROUND ART

For example, Patent Document 1 proposes that a fluidized silanol compound is formed on a substrate by reacting an oxygen-containing silicon compound gas as a film forming gas with a non-oxidizing hydrogen-containing gas in a state where at least the non-oxidizing hydrogen-containing gas is in a plasma state, and the substrate is annealed to make the silanol compound an insulating film.

### CITATION LIST

### Patent Literature

### Patent Document 1: WO 2021/010004

### SUMMARY OF INVENTION

### Technical Problem

The present disclosure provides a technique for improving embeddability of a flowable film embedded in a recess.

### Solution to Problem

According to an aspect of the present disclosure, an embedding method of embedding a film in a recess of a substrate is provided. The embedding method includes: (a) preparing a substrate having a recess on a mounting table arranged in a chamber of a substrate processing apparatus; (b) forming a flowable film in the recess; and (c) performing a first modification on the flowable film with a plasma generated by supplying RF power to the mounting table.

### Advantageous Effects of Invention

According to one aspect, embeddability of a flowable film embedded in a recess can be improved.

### BRIEF DESCRIPTION OF THE DRAWINGS

FIG. 1 is a flowchart illustrating an example of an embedding method ST according to an embodiment;

FIG. 2 is a cross-sectional diagram of a film for explaining the embedding method ST according to an embodiment;

FIG. 3 is a diagram illustrating an embedding failure of a flowable film in a recess;

FIG. 4 is a diagram illustrating a reaction example when a flowable film is formed and modified to form a SiO film;

FIG. 5 is a diagram illustrating a reaction example when a flowable film is formed and modified to form a SiN film;

FIG. 6 is a diagram illustrating a reaction example when a flowable film is formed and modified to form a BN film;

FIG. 7 is a diagram illustrating a reaction example when a flowable film is formed and modified to form a SiC film; and

FIG. 8 is a configuration example of a substrate processing apparatus according to an embodiment.

### DESCRIPTION OF EMBODIMENTS

In the following, an embodiment of the present disclosure will be described with reference to the drawings. In each of the drawings, the same components will be denoted by the same reference numerals, and repeated explanations may be omitted.

In the present specification, the directions such as parallel, right angle, orthogonal, horizontal, vertical, up and down, left and right are allowed to deviate to a degree that does not detract from the effect of the embodiment. The shape of the corners is not limited to a right angle, but may be rounded in an arcuate shape. The terms parallel, right angle, orthogonal, horizontal, vertical, circle, and coincident may include substantially parallel, substantially right angle, substantially orthogonal, substantially horizontal, substantially vertical, substantially circle, and substantially coincident.

### [Embedding Method ST]

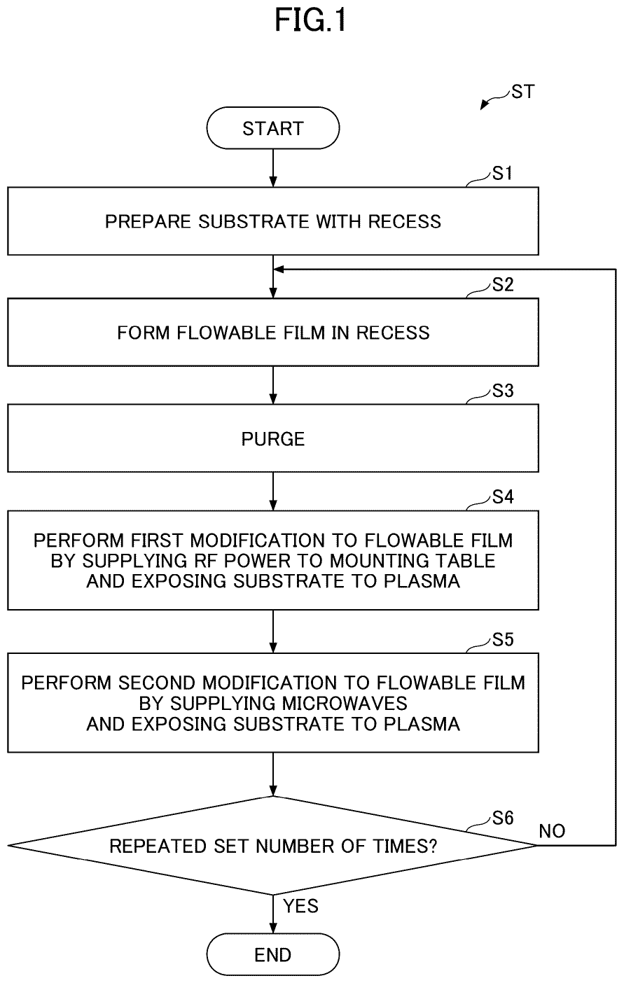

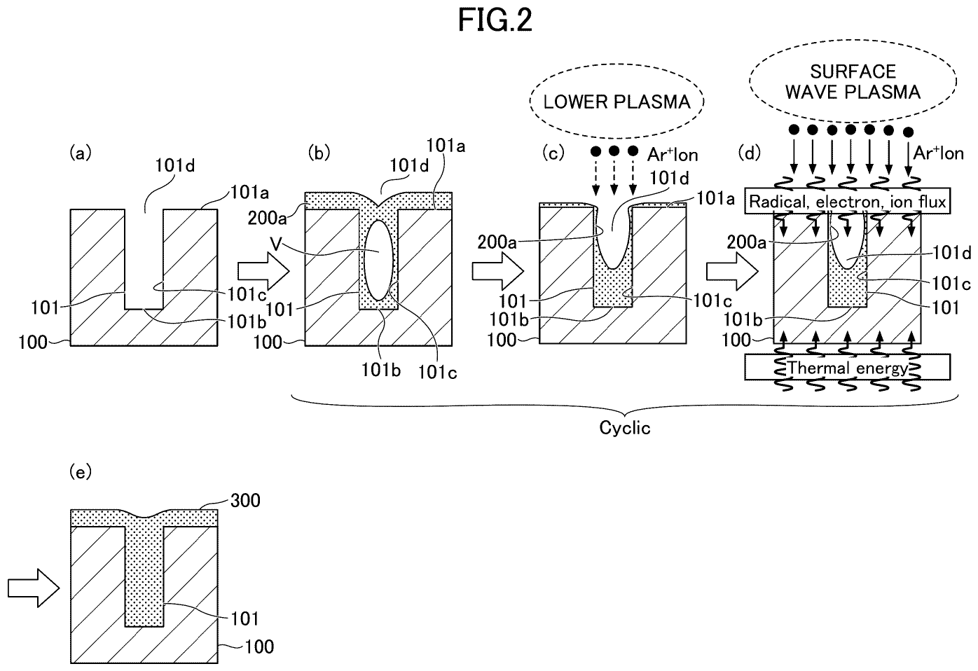

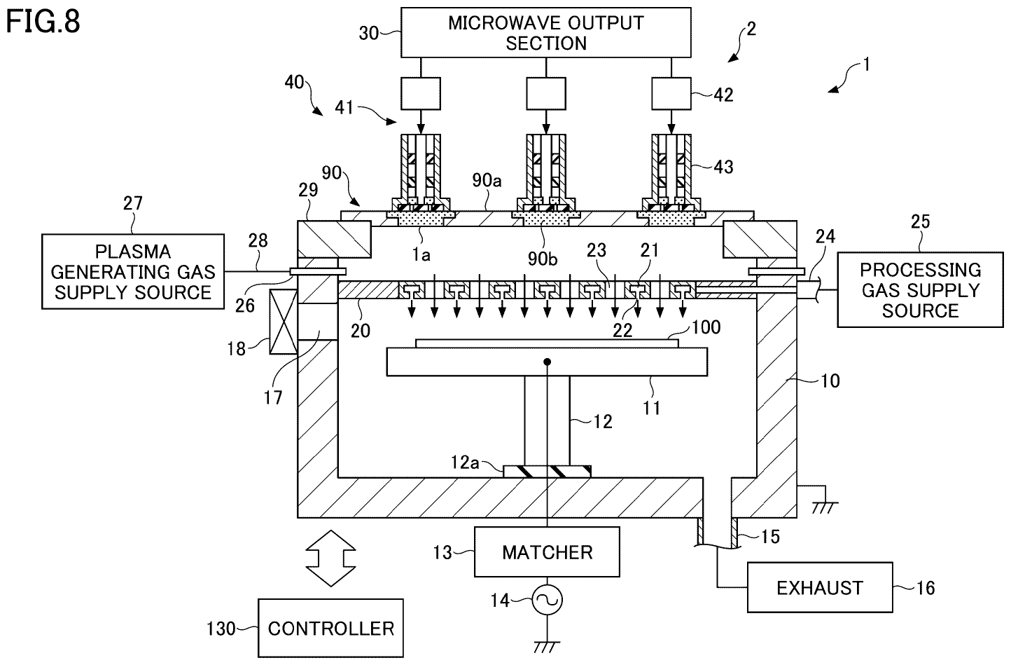

First, an embedding method ST according to an embodiment will be described with reference to FIGS. 1 and 2. FIG. 1 is a flowchart illustrating an example of the embedding method ST according to an embodiment. FIG. 2 is a cross-sectional diagram of a film for explaining the embedding method ST according to an embodiment. In the embedding method ST of FIG. 1, for example, a flowable film is embedded in a recess 101 of a substrate 100 as illustrated in FIG. 2(a) by using a fluidized CVD technique, and the flowable film is modified to form an insulating film or the like. This embedding process is executed by, for example, a substrate processing apparatus 1 (see FIG. 8) described later. The substrate processing apparatus 1 includes a chamber 10, a mounting table 11 arranged in the chamber 10, an RF power source 14 connected to the mounting table 11, a plasma source 2 arranged above the chamber 10 to supply microwaves, and a controller 130. The embedding method ST is controlled by the controller 130.

### (Step S1)

First, in step S1 of FIG. 1, the controller 130 prepares the substrate 100 having a recess 101 on the mounting table 11. The substrate 100 to be prepared is not particularly limited, but examples thereof include a semiconductor substrate such as silicon. As the substrate 100, a substrate having a fine three-dimensional structure on its surface can be used. The fine three-dimensional structure may include a structure in which a fine pattern is formed. The fine pattern has, for example, the recess 101 as illustrated in FIG. 2(a). The recess 101 may be, for example, a trench or a hole. A base is not particularly limited.

The recess 101 is composed of a top surface 101a, a bottom surface 101b, and a side surface 101c, and has an opening 101d opening in the upper portion of the recess 101. In step S1, the substrate 100 is carried into the chamber 10 of the substrate processing apparatus 1.

### (Step S2)

Next, in step S2 of FIG. 1, the controller 130 forms a flowable film having a predetermined thickness in the recess 101. For example, as illustrated in FIG. 2(b), a flowable film 200a having a predetermined thickness is formed in the recess 101.

As an example of a method of forming the flowable film 200a, a raw material gas, a hydrogen-containing gas, and a reaction promoting gas are supplied into the chamber 10, a microwave is supplied as an example of an electromagnetic wave from the plasma source 2, plasma (also referred to as surface wave plasma) is generated in the upper portion of the chamber 10, and the reaction promoting gas is reacted with the raw material gas and the hydrogen-containing gas in a state in which at least the reaction promoting gas is in a plasma state. Thus, the flowable film 200a is formed. In step S2, RF power is not supplied from the RF power source 14 to the mounting table 11.

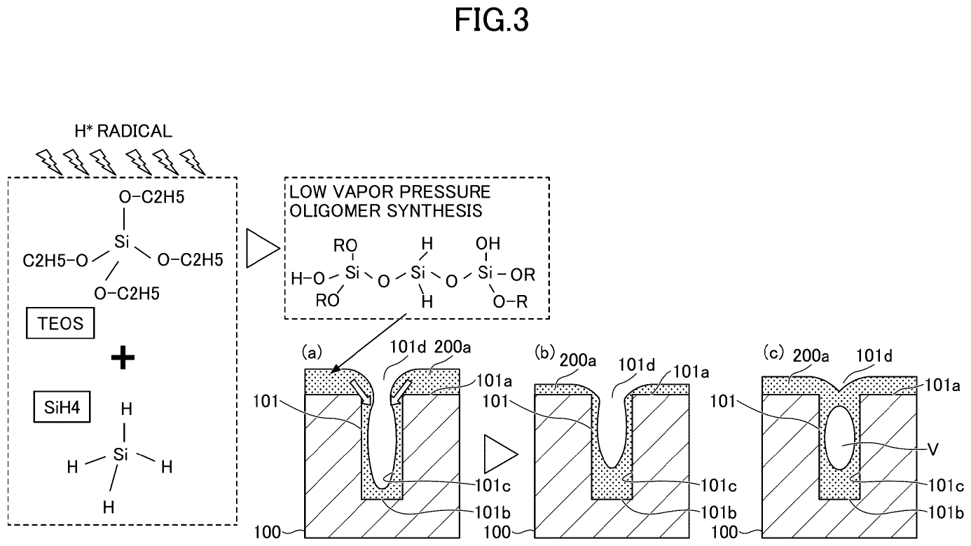

For example, a low vapor pressure oligomer illustrated in FIG. 3(a) is synthesized from tetraethoxysilane (TEOS; Si (OC₂H₅)₄) gas illustrated in FIG. 3, which is an example of the Si raw material gas, silane (SiH₄) gas, which is an example of the hydrogen-containing gas, and hydrogen gas, which is an example of the reaction promoting gas, and the flowable film 200a of the oligomer is generated. In this case, hydrogen gas is converted into plasma using surface wave plasma, and the activated hydrogen radical (H radical: H⁺) is reacted with the TEOS gas, which is an example of the raw material gas, and the silane gas, which is an example of the hydrogen-containing gas. The H radical breaks the bond of the TEOS gas and the silane gas to form the low vapor pressure oligomer illustrated in FIG. 3(a).

During the film formation in step S2, the flowable film 200a is liquefied by setting the temperature in the chamber to a low temperature (for example, less than 250° C.). According to the properties as a liquid of the flowable film 200a, the flowable film 200a flows from the top surface 101a of the recess 101 into the recess 101 as illustrated by arrows in FIG. 3(a), and accumulates on the bottom surface 101b of the recess 101 as illustrated in FIG. 3(b).

However, when the opening 101d of the recess 101 becomes small, the opening 101d is blocked by the flowable film 200a, as illustrated in FIG. 3(c), and a void V is formed inside the recess 101, which may cause an embedding failure. When the viscosity of the flowable film 200a increases, the embedding failure tends to occur. The viscosity of the flowable film 200a may be increased due to cooling of the flowable film 200a in the substrate 100 controlled at a low temperature, an increase in the molecular weight of the low vapor pressure oligomer, a shortage of side chain alkyl groups, or the like.

Therefore, in the embedding method ST of the present disclosure, in step S4, which will be described later, RF power (lower RF power) is supplied to the mounting table 11, and plasma (also referred to as lower plasma) is generated near the substrate 100 on the mounting table 11 arranged in the chamber 10 to assist the embedding of the flowable film 200a. Thus, occurrence of the void V is avoided, and the flowable film 200a can be embedded in order from the bottom surface 101b of the recess 101.

### (Step S3)

Next, in step S3 of FIG. 1, the controller 130 supplies a purge gas into the chamber 10 to remove the raw material gas and the hydrogen-containing gas remaining in the chamber 10. As the purge gas, for example, an inert gas is used. As the inert gas, a noble gas such as Ar gas, or a gas such as He gas or N₂ gas is used. A gas such as Ar gas that tends to become a plasma, and a gas such as N₂ gas that is less likely to become a plasma than Ar gas, has low reactivity, and does not generate radicals may be mixed and used.

### (Step S4)

Next, in step S4 in FIG. 1, the controller 130 performs a first modification on the flowable film 200a.

In step S4, the controller 130 supplies RF power (lower RF power) from the RF power source 14 to the mounting table 11, and performs a first modification on the flowable film 200a by the generated lower plasma of the purge gas. In step S4, no microwave is supplied from the plasma source 2. In step S4, in order to generate a weak plasma, low-power RF power (lower RF power) is supplied from the RF power source 14 to the mounting table 11.

The low-power RF power (lower RF power) is of a power (for example, 500 W or less) such that the molecules of the flowable film 200a are not decomposed. However, even when the RF power (lower RF power) is controlled to be low, in the case where the raw material gas is present in the chamber 10, the raw material gas may be decomposed by the RF power (lower RF power) supplied to the mounting table 11. Therefore, in step S3, the raw material gas is purged and the RF power (lower RF power) is supplied in an atmosphere such as Ar gas. Thus, the flowable film 200a is pushed into the inner part by the collision of Ar ions and the like in the lower plasma, while avoiding the formation of the flowable film 200a with poor coverage due to the decomposition of the raw material gas in the first modification of step S4. Thus, the embeddability of the flowable film 200a in the recess 101 can be improved. Further, the surface temperature of the flowable film 200a can be increased by the ion energy of Ar ions and the like in the lower plasma and the thermal energy from the plasma. As a result, the viscosity coefficient of the flowable film 200a can be decreased by increasing the surface temperature of the flowable film 200a, and the fluidity of the flowable film 200a can be increased. Thus, with reduced viscosity and increased fluidity, the flowable film 200a can be easily pushed into the recess 101. In addition, ions are drawn downward by the RF power (lower RF power). Due to the physical collision of ions, the flowable film 200a in the upper portion of the recess 101 is given a downward force by the anisotropy of the kinetic energy of the ions. Thus, the flowable film 200a that blocks the opening 101d can be pushed deep into the recess 101 (on the side of the bottom surface 101b). As a result, the embeddability of the flowable film 200a can be improved.

Thus, even when the highly viscous flowable film 200a is generated due to, for example, process conditions, it is possible to avoid the occurrence of the void V and to improve the embeddability of the flowable film 200a in the recess 101. For example, the flowable film 200a at the opening 101d of the recess 101 illustrated in FIG. 2(b) can be pushed into the recess 101 to open the upper portion of the recess 101 in, for example, a V-shape as illustrated in FIG. 2(c).

In step S4, the RF power (lower RF power) may be a continuous wave or a pulse wave. The microwave supplied from the plasma source 2 generates the surface wave plasma in the upper portion of the chamber 10. Therefore, it is difficult to promote the embedding of the flowable film 200a into the recess 101 of the substrate 100 arranged in the lower portion of the chamber 10. Therefore, in step S4, the supply of the microwave is stopped.

### (Step S5)

After step S4 in FIG. 1, in step S5, a microwave is supplied, and the flowable film 200a is exposed to the surface wave plasma to perform a second modification of the flowable film 200a.

For example, as illustrated in FIG. 2(d), by exposing the flowable film 200a to the generated surface wave plasma, chemical and physical reactions are promoted by radicals, electrons, and ions in the plasma, and the flowable film 200a is modified. As a result, the flowable film 200a is changed from a liquid to a solid and is modified into a uniform film having good film characteristics. In the example illustrated in FIG. 2(d), the substrate is heated by a heating section (a heater and the like) for heating the substrate 100 together with the modification by the surface wave plasma (radicals, electrons, and ions). In this case, the flowable film 200a is modified by the energy of the surface wave plasma and the thermal energy by the heating section. The formation of the flowable film 200a illustrated in FIG. 2(b) and the first modification of the flowable film by the low-power RF power (lower RF power) illustrated in FIG. 2(c) can be performed in the same chamber 10. Further, the second modification of the flowable film 200a by the surface wave plasma illustrated in FIG. 2(d) may be performed in the same chamber 10 or in a different chamber. The second modification in step S5 may be performed every time after the first modification in step S4, may be performed at a predetermined frequency after the first modification in step S4, or may not be performed.

### (Step S6)

Next, in accordance with the determination in step S6 of FIG. 1, the controller 130 repeats the processes of steps S2 to S5 for a set number of times. Thus, the formation of the flowable film 200a, and the first modification and the second modification of the flowable film 200a are repeated for a set number of times, and then the process ends.

The method of embedding a film in the recess 101 described above includes (a) preparing a substrate having the recess 101 on the mounting table 11; (b) forming the flowable film 200a in the recess 101; and (c) performing the first modification on the flowable film 200a with the plasma generated by supplying the RF power (lower RF power) from the RF power source 14 to the mounting table 11.

In the embedding method, (b) the forming of the flowable film 200a and (c) the first modification on the flowable film 200a may be repeated to stack a plurality of flowable films from the bottom surface 101b of the recess 101.

In the embedding method, after (c) the first modification on the flowable film 200a, (d) the second modification of the flowable film 200a after the first modification by energy of the electromagnetic wave and/or the thermal energy by heating may be performed.

Further, in the embedding method, (b) the formation of the flowable film 200a, (c) the first modification of the flowable film 200a, and (d) the second modification of the flowable film 200a may be repeated to stack a plurality of flowable films from the bottom surface 101b of the recess 101. A plurality of flowable films are also collectively referred to as the flowable film 200a.

According to the above-described embedding method ST, as illustrated in FIG. 2(e), an insulating film 300 formed by modifying each of the stacked flowable films 200a can be embedded in the recess 101 without voids. The modification of the flowable film 200a includes pushing the flowable film 200a into the recess, solidification, and change in film characteristics. After the formation of the insulating film 300, a planarization (CMP) process may be performed.

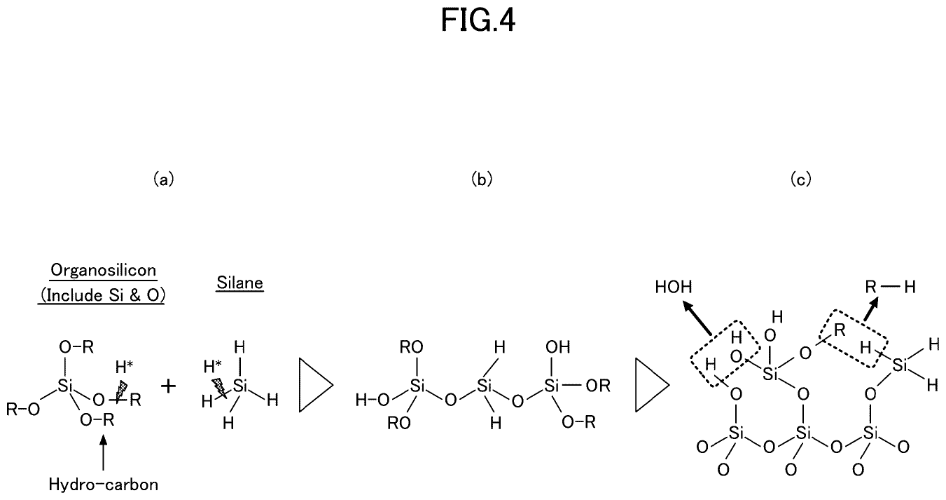

Next, (1) film forming conditions of the flowable film, (2) first modification conditions of the flowable film, and (3) second modification conditions of the flowable film will be described with reference to FIG. 4. FIG. 4 is a diagram illustrating a reaction example when a flowable film is formed and modified to form a SiO film. In FIG. 4, an example of forming a SiO insulating film will be described.

### (1) Film Forming Conditions of Flowable Film (Step S2 in FIG. 1)

### (Gas Species)

In order to form the flowable film 200a, as illustrated in FIG. 4(a), an oxygen-containing silicon compound gas and a non-oxidizing hydrogen-containing gas are supplied to the chamber 10 as film forming gases. In the example illustrated in FIG. 4(a), the film forming gases are tetraethoxysilane (TEOS; Si(OC₂H₅)₄) having a Si—O skeleton having an alkyl group (R) and a silane (SiH₄) gas. Here, TEOS, the silane (SiH₄) gas, and a H₂ gas are supplied. TEOS is an example of the oxygen-containing silicon compound gas, and the silane gas is an example of the hydrogen-containing gas.

Other examples of the oxygen-containing silicon compound gas include tetramethoxysilane (TMOS; Si(OCH₃)₄), methyltrimethoxysilane (MTMOS; Si(OCH₃)₃CH₃), dimethyldimethoxysilane (DMDMOS; Si(OCH₃)₂(CH₃)₂), triethoxysilane (SiH(OC₂H₅)₃), trimethoxysilane (SiH(OCH₃)₃), trimethoxydisiloxane (Si(OCH₃)₃OSi(OCH₃)₃), and the like. These compounds may be used alone or in combination of two or more.

Another example of the hydrogen-containing gas is an NH₃ gas. The hydrogen-containing gas may be used alone or in combination of two or more. In addition to the oxygen-containing silicon compound and the hydrogen-containing gas, an inert gas such as He, Ne, Ar, Kr, and N₂ may be supplied into the chamber. The hydrogen-containing gas may be at least one selected from H₂ gas, NH₃ gas, and SiH₄ gas, or at least one of these gases may be further added with at least one of the oxygen-containing gases such as O₂ gas, NO, N₂O, CO₂, and H₂O as an additive gas.

Plasma is generated, and the flowable film 200a is formed by fluidized CVD. The plasma generation method is not particularly limited, and various methods such as capacitively coupled plasma, inductively coupled plasma, and microwave plasma may be used. The plasma may be such that at least the hydrogen-containing gas is in a plasma state. That is, both the film forming gas and the hydrogen-containing gas may be in a plasma state, or only the hydrogen-containing gas may be in a plasma state.

Here, H₂ gas is converted into plasma. Through the reaction with the plasma, a silanol compound having fluidity is formed on the substrate as the flowable film 200a. Here, the silanol compound refers to a silicon-containing monomer and oligomer (multimer) having a Si—OH group.

Specifically, as illustrated in FIGS. 4(a) and (b), TEOS and the silane gas react with an H radical (H⁺) in the plasma generated from the H₂ gas, and an alkyl group and hydrogen are removed to form a silanol compound monomer (for example, orthosilicic acid or methyltriol). Further, by the reaction with the plasma, a part of TEOS introduced as the film forming gas is polymerized to form a polysilanol oligomer, and a hydrocarbon group and the like are similarly removed from the polysilanol oligomer to form a silanol compound oligomer. The silanol compound in the monomer and the low vapor pressure oligomer state thus generated on the substrate 100 has fluidity and is embedded in the recess 101 as the flowable film 200a.

### (Temperature and Pressure)

From the viewpoint of ensuring fluidity of the flowable film 200a, when the flowable film 200a is formed, the temperature of the substrate 100 (or the temperature of the mounting table) is preferably controlled to 250° C. or less, more preferably −10° C. to 100° C., and still more preferably −10° C. to 50° C. When the flowable film 200a is formed, the pressure in the chamber 10 is preferably 10 Pa to 2,600 Pa.

### (2) First Modification Conditions of Flowable Film (Step S4 in FIG. 1)

The frequency of the RF output from the RF power source 14 is 100 Hz to 40 MHz. The frequency of the RF output from the RF power source 14 is more preferably 450 kHz to 13.56 MHZ.

The RF power (lower RF power) output from the RF power source 14 is 10 W to 500 W. The RF power (lower RF power) is more preferably 50 to 300 W. The RF power (lower RF power) is dependent on the RF frequency. It is preferable to lower the power as the RF frequency is lower. The pressure in the chamber 10 is 50 Pa to 500 Pa.

The low-power RF power (lower RF power) satisfying the conditions is supplied from the RF power source 14 to the mounting table 11. Ar gas, which is a purge gas, is converted into a plasma by the low-power RF power (lower RF power), and by exposing the substrate 100 to weak lower plasma formed near the mounting table 11, the first modification on the flowable film 200a is performed.

It is conceivable that, instead of supplying the low-power RF power (lower RF power) to the mounting table 11, the temperature of the substrate is controlled to improve the embeddability of the flowable film 200a into the recess 101.

However, the temperature control of the substrate takes time and reduces productivity. In addition, it is also assumed that temperature control is limited as a process condition. According to the present method, the embeddability of the flowable film can be improved without temperature control.

### (3) Second Modification Conditions of Flowable Film (Step S5 in FIG. 1)

In the second modification of the flowable film 200a, the surface wave plasma is generated and radicals, electrons, and ions are supplied to the flowable film 200a. As a result, as illustrated in FIG. 4(c), a dehydration condensation reaction and cleavage of alkyl groups R occur in the silanol compound. As a result, the excess substances such as H2O and R—H become a gas phase and volatilize, Si—O—Si bonds are formed, and a SiO film having a network structure of Si and O is formed as an insulating film.

In the second modification, the flowable film 200a is modified by heat (annealing) by heating the substrate 100, and the silanol compound embedded in the recess 101 is changed into a silicon-based insulating film. In the heat treatment, the molecules of the flowable film 200a are vibrated by thermal energy, and the excess substances are desorbed by the vibration energy. When the flowable film 200a is modified by heat, because there is no striking by ions or the like, physical damage to the structure having the recess 101 is small. In the second modification of the flowable film 200a, only plasma may be used, or only heat may be used.

### (Gas Species)

In the second modification of the flowable film 200a, the plasma may be generated using a gas excluding the raw material gas containing Si, among the gases used in the film formation of the flowable film 200a. For example, in the case where a double source gas of the TEOS gas and the silane gas is used as the film forming gas, and further the hydrogen (H₂) gas and the argon (Ar) gas are used in the film formation of the flowable film 200a, the H₂ gas and the Ar gas may be supplied to generate a plasma in the second modification of the flowable film 200a.

### (Temperature and Pressure)

The second modification of the flowable film 200a may be performed in the same chamber as the chamber 10 in which the flowable film 200a is formed and the first modification is performed, or may be performed in a different chamber. When the second modification is performed in a different chamber from the chamber 10 in which the first modification is performed, the temperature of the substrate in the chamber may be controlled to be higher than 250° C., which is the temperature of the substrate at the time the flowable film 200a is formed, from the viewpoint of promoting the modification.

### (Types of Insulating Film)

The insulating film 300 formed by forming and modifying the flowable film 200a by the above-described embedding method ST may include a SiO film, a SiN film, a SiC film, a SiOCH film, a SiOC film, a BN film, a TiO film, and an AlO film. The raw material gas may be any one of a silicon-containing gas, a boron-containing gas, a titanium-containing gas, and an aluminum-containing gas.

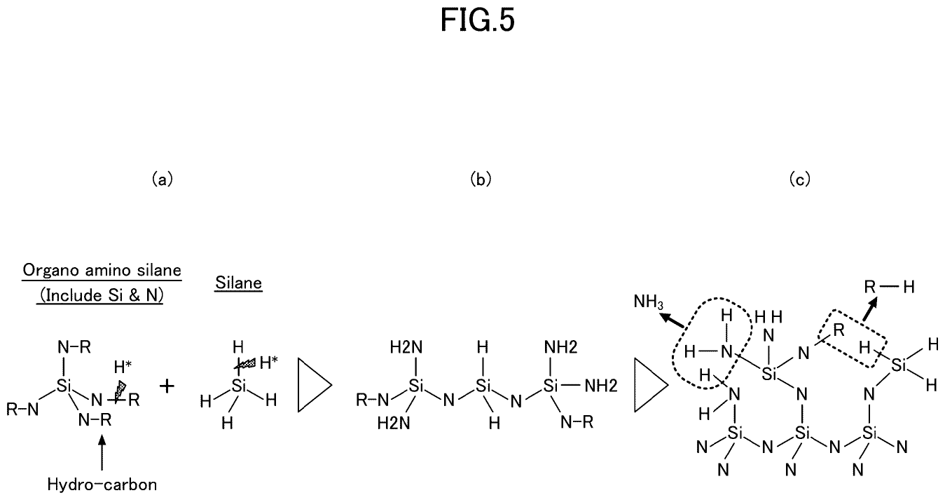

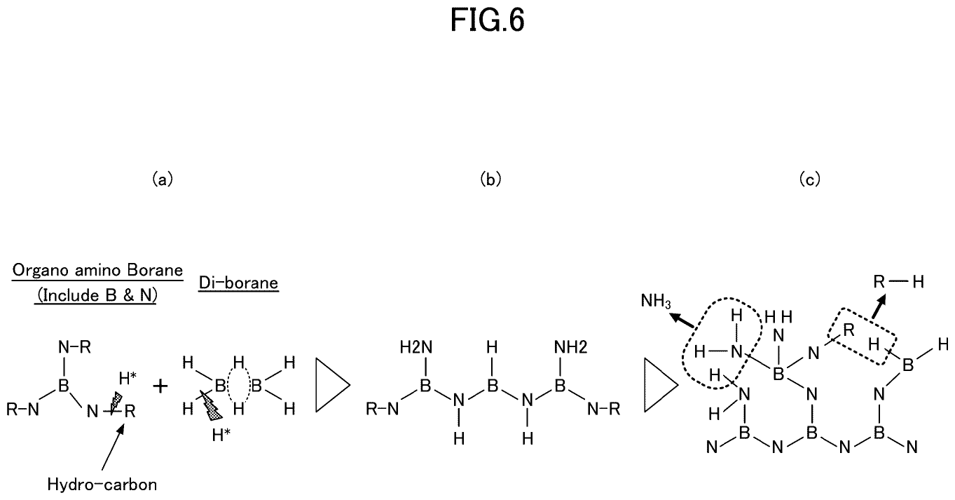

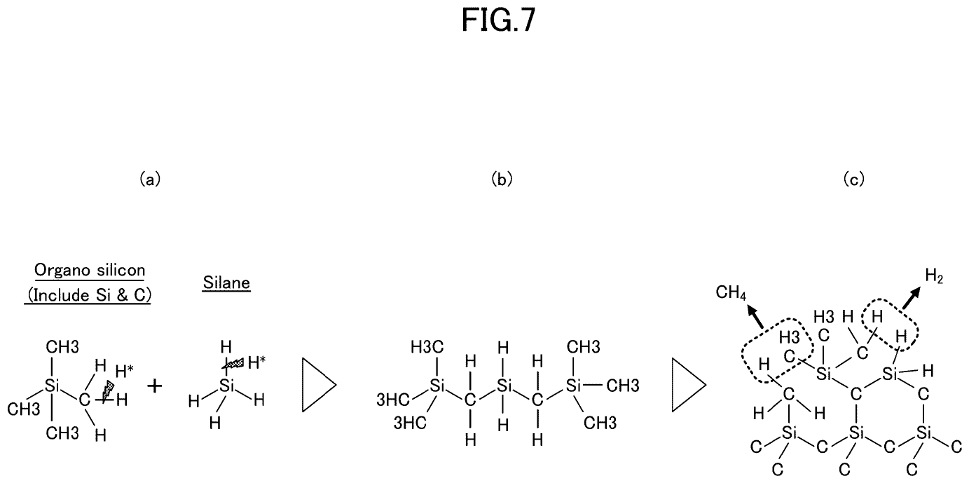

FIG. 5 is a diagram illustrating a reaction example when the flowable film 200a is formed and modified to form a SiN film. FIG. 6 is a diagram illustrating a reaction example when the flowable film 200a is formed and modified to form a BN film. FIG. 7 is a diagram illustrating a reaction example when the flowable film 200a is formed and modified to form a SiC film.

When the SiN film illustrated in FIG. 5 is formed, in order to form the flowable film 200a, as illustrated in FIG. 5(a), a double source gas of an organic aminosilane having a Si—N skeleton having an alkyl group (R) and the silane (SiH₄) gas is supplied as the film forming gas to the chamber 10. Further, the hydrogen-containing gas and the argon gas are supplied. Examples of the organic aminosilane include diethylaminotrimethylsilane, dimethylaminotrimethylsilane, ethylmethylaminotrimethylsilane, bis (tert-butylamino) silane, trisdimethylaminosilane, 2,2,4,4,6,6-hexamethylcyclotrisilazane, 1,3-diisopylamino-2, 4-dimethylcyclosilazane, and the like.

As illustrated in FIGS. 5(a) and (b), the organic aminosilane reacts with the plasma (H and NH radicals) of the hydrogen-containing gas to form the flowable film 200a of monomers and oligomers in which the bonds of Si—H and N—R (and N—C) are broken and the alkyl group and hydrogen are removed.

By supplying radicals, electrons, and ions to the chamber 10, the flowable film 200a is exposed to the plasma and modified. Further, the substrate 100 is heated and the flowable film 200a is heat-treated (annealed). Thus, as illustrated in FIG. 5(c), NH₃ and alkyl groups R are cleaved, and NH₃ and R—H become a gas phase and volatilize to form Si—N—Si bonds. As a result, a SiN film having a network structure of Si and N is formed as the insulating film 300.

When the BN film illustrated in FIG. 6 is formed, in order to form the flowable film 200a, as illustrated in FIG. 6(a), a double source gas of an organic aminoborane gas having a B—N skeleton having an alkyl group (R) and a diborane gas is supplied as the film forming gas to the chamber 10. Further, the hydrogen-containing gas and the argon gas are supplied. Examples of the organic aminoborane include trisdimethylaminoborane, trisethylmethylaminoborane, borazine, and the like.

As illustrated in FIGS. 6(a) and (b), the organic aminoborane reacts with the plasma (H and NH radicals) of the hydrogen-containing gas to form the flowable film 200a of monomers and oligomers in which the bonds of B—H and N—R (and N—C) are broken and the alkyl group and hydrogen are removed.

By supplying radicals, electrons, and ions to the chamber 10, the flowable film 200a is exposed to the plasma and modified. Further, the substrate 100 is heated and the flowable film is heat-treated (annealed). Thus, as illustrated in FIG. 6(c), NH₃ and alkyl groups R are cleaved, NH₃ and R—H become a gas phase and volatilize, B—N—B bonds are formed, and a BN film having a network structure of B and N is formed as the insulating film 300.

When the SiC film illustrated in FIG. 7 is formed, in order to form the flowable film 200a, as illustrated in FIG. 7(a), a double source gas is supplied as the film forming gas to the chamber 10, and the hydrogen-containing gas and the argon gas are further supplied. In the example illustrated in FIG. 7(a), a film-forming precursor is a double source gas of an organic silicon-containing gas having a Si—C skeleton and the silane gas. Examples of the organic silicon-containing gas include bisdichlorosilylmethylene, bistrimethylsilylamine, and the like.

As illustrated in FIGS. 7(a) and 7(b), the organic silicon-containing gas reacts with the plasma (H radical) of the hydrogen-containing gas to form the flowable film 200a of monomers and oligomers in which the bonds of Si—H and C—H are broken and hydrogen is removed.

By supplying radicals, electrons, and ions to the flowable film 200a, the flowable film 200a is exposed to the plasma and modified. Further, the substrate 100 is heated and the flowable film is heat-treated (annealed). Thus, as illustrated in FIG. 7(c), CH₄ and H₂ volatilize, C—Si—C bonds are formed, and a SiC film having a network structure of Si and C is formed as the insulating film 300.

When the TiO film is formed, a titanium-containing gas composed of any one of a titanium compound, tetrakis dimethylamino titanium, TiCp (NMe₂)₃, TiMe₅Cp (NMe₂)₃, or titanium tetrachloride is reacted with the hydrogen-containing gas in a state where at least the hydrogen-containing gas is in a plasma state, and a flowable titanium compound containing oxygen is formed on the substrate. Then, the substrate is modified and the titanium compound containing oxygen is formed as the insulating film.

When the AlO film is formed, an aluminum-containing gas composed of any one of aluminum compounds, AICl₃NH₃, (NH₄)₃AIF₆, and Al(i-Bu)₃ is reacted with the hydrogen-containing gas in a state where at least the hydrogen-containing gas is in a plasma state, and a flowable aluminum compound containing oxygen is formed on the substrate. Then, the substrate is modified and the aluminum compound containing oxygen is formed as the insulating film.

### [Substrate Processing Apparatus]

Next, a configuration example of the substrate processing apparatus 1 that executes the embedding method ST of the present disclosure will be described with reference to FIG. 8. FIG. 8 is a diagram illustrating a configuration example of the substrate processing apparatus 1 according to an embodiment. The substrate processing apparatus 1 includes the chamber 10.

The substrate processing apparatus 1 executes the embedding method ST under the control of the controller 130, and embeds a flowable film in the recess 101 of the substrate 100 in the chamber 10 in a reduced pressure state, using a fluidized CVD technique. The substrate processing apparatus 1 performs at least the first modification on the flowable film to form the insulating film or the like. The substrate processing apparatus 1 may perform the second modification on the flowable film after the first modification.

The configuration of the substrate processing apparatus 1 illustrated in FIG. 8 is an example. The substrate processing apparatus 1 may be any type of plasma processing apparatus of Capacitively Coupled Plasma (CCP), Inductively Coupled Plasma (ICP), Micro Surface Wave Plasma, Electron Cyclotron Resonance Plasma (ECR), Helicon Wave Plasma (HWP), and Radial Line Slot Array Antenna (RLSA).

As illustrated in FIG. 8, in the substrate processing apparatus 1, by arranging a plurality of independently controllable microwave plasma sources 2 in a plane, plasma uniformity can be ensured. Also, the plasma can be maintained in a wider pressure range compared to Inductively Coupled Plasma (ICP). Further, the substrate processing apparatus 1 has a structure in which a shower plate 20 is provided for separating a processing space (lower space) of the substrate 100 from a plasma generation space, cutting ion components, and preferentially introducing radicals into the lower space, and has a gas introduction structure in which a plurality of types of raw material precursors can be supplied into the lower space where the substrate 100 is arranged. Further, the substrate processing apparatus 1 has a stage structure in which the substrate is controlled to the temperature at which the fluidity is exhibited. From the above, as an apparatus structure for forming the flowable film 200a, the microwave plasma processing apparatus illustrated in FIG. 8 is preferably used as the substrate processing apparatus 1.

The substrate processing apparatus 1 includes: the substantially cylindrical grounded chamber 10 made of a metal material such as aluminum or stainless steel that is airtightly sealed; and the plasma source 2 for forming the microwave plasma in the chamber 10. An opening la is formed in the upper portion of the chamber 10, and the plasma source 2 is provided so as to face the inside of the chamber 10 from the opening la.

The mounting table 11 for horizontally supporting the substrate 100 is provided in the chamber 10 in a state supported by a cylindrical support member 12 erected at the center of the bottom surface of the chamber 10 via an insulating member 12a. Examples of the material constituting the mounting table 11 and the support member 12 include aluminum whose surface is anodized.

Further, although not illustrated, the mounting table 11 is provided with an electrostatic chuck for electrostatically attracting the substrate 100, a temperature control mechanism, a gas passage for supplying a heat transfer gas to the rear surface of the substrate 100, and a lifting pin that raises and lowers to transport the substrate 100.

An exhaust pipe 15 is connected to the bottom surface of the chamber 10, and an exhaust 16 including a vacuum pump is connected to the exhaust pipe 15. By operating the exhaust 16, the inside of the chamber 10 is exhausted, and the inside of the chamber 10 can be decompressed at a high speed to a predetermined degree of vacuum. On the side wall of the chamber 10, a loading/unloading port 17 for loading/unloading the substrate 100, and a gate valve 18 for opening/closing the loading/unloading port 17 are provided.

A shower plate 20 is horizontally provided at a position above the mounting table 11 in the chamber 10. The shower plate 20 includes gas passages 21 formed in a grid shape in a top view, and a number of gas discharge holes 22 formed in the gas passages 21, and a space 23 is provided between the grid-shaped gas passages 21. A pipe 24 extending outside the chamber 10 is connected to the gas passages 21 of the shower plate 20, and a processing gas supply source 25 is connected to the pipe 24.

A ring-shaped plasma generating gas introducing member 26 is provided along the chamber side wall at a position above the shower plate 20 of the chamber 10, and the plasma generating gas introducing member 26 is provided with a number of gas discharge holes on its inner periphery. A plasma generating gas supply source 27 for supplying a plasma generating gas (purge gas) is connected to the plasma generating gas introducing member 26 via a pipe 28.

The RF power source 14 is electrically connected to the mounting table 11 via a matcher 13. The RF power (lower RF power) is supplied from the RF power source 14 to the mounting table 11.

The plasma source 2 is arranged on a top plate 90 provided above the chamber 10. The plasma source 2 includes a microwave output section 30 for outputting microwaves by distributing the microwaves to a plurality of paths, and a microwave supply section 40 for transmitting the microwaves output from the microwave output section 30 and radiating them into the chamber 10.

The microwave output section 30 generates, for example, PLL oscillation of microwaves having a predetermined frequency (for example, 860 MHZ). In addition to 860 MHz, the frequency of the microwave may range from 700 MHz to 3 GHZ.

The microwave supply section 40 includes a plurality of antenna modules 41 for guiding the microwaves distributed by the distributors in the microwave output section 30 into the chamber 10. Each of the antenna modules 41 includes an amplifier 42 for mainly amplifying the distributed microwaves and a microwave radiator 43. The microwave is radiated into the chamber 10 from the antenna of the microwave radiator 43 in each of the antenna modules 41. The microwave supply section 40 includes seven antenna modules 41. Among seven microwave radiators 43 of the antenna modules, six are arranged circumferentially and one is arranged at the center thereof, on a circular top plate 90.

The top plate 90 functions as a vacuum seal and a microwave transmission plate, and includes a metal frame 90a and a dielectric member 90b made of a dielectric such as quartz and fitted into the frame 90a so as to correspond to a portion where the microwave radiator 43 is arranged. The top plate 90 closes the opening 1a of the chamber 10 via a member 29.

The substrate processing apparatus 1 includes the controller 130. The controller 130 is, for example, a computer and includes a program storage (not illustrated). The program storage stores a program for controlling the processing of the substrate W, for example, a semiconductor wafer, in the substrate processing apparatus 1. The program may be stored in a computer-readable storage medium such as a computer-readable hard disk (HD), a flexible disk (FD), a compact disk (CD), a magnet optical desk (MO), or a memory card, and installed in the controller 130 from the storage medium.

In the substrate processing apparatus 1 having such a configuration, in the formation of the flowable film 200a, the plasma source 2 outputs microwaves, and the supply of the RF power (lower RF power) from the RF power source 14 is stopped.

In the formation of the flowable film 200a, the processing gas supplied from the processing gas supply source 25 may be a gas used for forming the flowable film 200a, for example, a double source gas of the TEOS gas and the silane gas. As the plasma generating gas supplied from the plasma generating gas supply source 27, the H₂ gas and the Ar gas are preferably used. Thus, the double source gas is not dissociated in the lower space as much as possible, and the dissociation of the H₂ gas and the Ar gas in the upper space can be promoted by the surface wave plasma of the microwave.

In the first modification of the flowable film 200a, the output of the microwave from the plasma source 2 is stopped, and the RF power (lower RF power) from the RF power source 14 is supplied. In the first modification of the flowable film 200a, the supply of the double source gas from the processing gas supply source 25 is stopped. The Ar gas or the like is preferably used as the purge gas from the plasma generating gas supply source 27. The supplied Ar gas is introduced into the lower space through the space 23 of the shower plate 20. The Ar gas is converted into a plasma by the RF power (lower RF power) to generate the lower plasma. At this time, surface wave plasma by the microwave is not generated. Therefore, Ar ions in the lower plasma are drawn into the substrate 100 side, and the first modification of the flowable film is performed.

In the second modification of the flowable film 200a, the output of the RF power (lower RF power) from the RF power source 14 is stopped, and microwaves are supplied from the plasma source 2. The Ar gas continued to be supplied is converted into a plasma, and radicals, electrons, and ions are supplied to the flowable film 200a. Thus, the second modification of the flowable film 200a is performed, and the insulating film 300 is formed (see FIG. 2).

As described above, according to the embedding method of the present embodiment, the fluidity (viscosity) of the flowable film embedded in the recess 101 can be adjusted, and the embeddability of the flowable film can be improved.

It should be considered that the embedding method and the substrate processing apparatus according to the disclosed embodiment are exemplary in all respects and not restrictive. The embodiments can be modified and improved in various forms without departing from the scope of the appended claims. The matters described in the above embodiments may be configured in other ways without being inconsistent, and may be combined without being inconsistent.

The present application claims priority to Japanese Patent Application No. 2022-037479, filed Mar. 10, 2022, with the Japanese Patent Office, the contents of which are incorporated herein by reference in their entirety.

### DESCRIPTION OF THE REFERENCE NUMERAL

1 Substrate processing apparatus
2 Plasma source

### 10 Chamber

11 Mounting table
14 RF power source

### 100 Substrate

### 101 Recess

101b Bottom surface

### 101d Opening

200a Flowable film
300 Insulating film

1. An embedding method of embedding a film in a recess of a substrate, the embedding method comprising:
(a) preparing a substrate having a recess on a mounting table arranged in a chamber of a substrate processing apparatus;
(b) forming a flowable film in the recess; and
(c) performing a first modification on the flowable film with a plasma generated by supplying RF power to the mounting table.

2. The embedding method according to claim 1, wherein, in (c), the first modification is performed to the flowable film by ion energy of the plasma and thermal energy of the plasma.

3. The embedding method according to claim 1, wherein, in (c), a purge gas is supplied into the chamber after (b) and the first modification is performed to the flowable film with a plasma of the purge gas.

4. The embedding method according to claim 1, wherein (b) the forming of the flowable film and (c) the performing of the first modification on the flowable film are repeated.

5. The embedding method according to claim 1, wherein a film type of the flowable film is any one of SiO, SiN, SiC, SiOCH, SiOC, BN, TiO, or AlO films.

6. The embedding method according to claim 1, wherein
the substrate processing apparatus includes: an RF power source connected to the mounting table; and a plasma source provided above the chamber and that is configured to supply an electromagnetic wave,
in (b), a raw material gas, a hydrogen-containing gas, and a reaction promoting gas are supplied into the chamber, and the reaction promoting gas is reacted with the raw material gas and the hydrogen-containing gas in a state in which at least the reaction promoting gas is in a plasma state by using the electromagnetic wave supplied from the plasma source, to form a flowable film;
the raw material gas is any one of a silicon-containing gas, a boron-containing gas, an aluminum-containing gas, or a titanium-containing gas; and
in (c), the first modification on the flowable film is performed by supplying RF power from the RF power source to the mounting table.

7. The embedding method according to claim 6, further comprising:
(d) performing a second modification on the flowable film after the first modification, by energy of the electromagnetic wave supplied from the plasma source, thermal energy by heating the mounting table, or both.

8. The embedding method according to claim 6, wherein, in (b), the supply of the RF power from the RF power source to the mounting table is stopped.

9. The embedding method according to claim 6, wherein, in (c), the supply of the electromagnetic wave from the plasma source is stopped.

10. The embedding method according to claim 7, wherein, in (d), the electromagnetic wave from the plasma source is supplied.

11. The embedding method according to claim 1, wherein a frequency of the RF power is 100 Hz to 40 MHz.

12. The embedding method according to claim 11, wherein the frequency of the RF power is 450 kHz to 13.56 MHz.

13. The embedding method according to claim 1, wherein the RF power is 10 W to 500 W.

14. The embedding method according to claim 13, wherein the RF power is 50 W to 300 W.

15. The embedding method according to claim 1, wherein the forming of the flowable film and the performing of the first modification on the flowable film are performed in a same chamber.

16. A substrate processing apparatus comprising:
a chamber;
a mounting table provided in the chamber;
an RF power source connected to the mounting table; and
a controller, wherein
the controller is configured to execute a method of embedding a film in a recess of a substrate, and
the controller is configured to control the embedding method of claim 1.
